(19) United States
(12) Patent Application Publication
(10) Pub. No.: US 2015/0037605 A1
(43) Pub. Date: Feb. 5, 2015

(54) MULTILAYER STRUCTURE AS REFLECTOR WITH INCREASED MECHANICAL STABILITY

(71) Applicants: Rafael Oser, Krefeld (DE); Timo Kuhlmann, Leichlingen (DE)

(72) Inventors: Rafael Oser, Krefeld (DE); Timo Kuhlmann, Leichlingen (DE)

(73) Assignee: Bayer MaterialScience AG, Leverkusen (DE)

(21) Appl. No.: 14/379,559

(22) PCT Filed: Dec. 19, 2012
(86) PCT No.: PCT/EP2012/076197

§ 371 Date: Aug. 19, 2014

Related U.S. Application Data
(63) Continuation of application No. 13/400,159, filed on Feb. 20, 2012.

(51) Int. Cl. C09D 5/08; C23C 30/00; H01L 31/052

(52) U.S. Cl. CPC C09D 5/08; H01L 31/0525; C23C 30/00
USPC 428/623

(57) ABSTRACT

The present invention relates to a multilayer structure as a reflector with increased mechanical stability, which comprises a substrate layer A, a barrier layer B, a metallic reflector layer C, an optional layer D, a plasma polymer layer E, and a covering layer comprising inorganic constituents, and the covering layer does not contain UV absorber.

The present invention relates to a multilayer structure for use as a mirror/reflector in the CPV (concentrating photovoltaics) and CSP (concentrating solar power) field. The multilayer structure comprises a substrate layer, a barrier layer, a metallic reflector layer, an optional oxidic layer and a further layer which can be a plasma polymer layer or a highly refractive metal oxide layer. The above-described structure is further protected from weathering influences and mechanical stress by a covering layer system according to the invention.

Silver mirrors for use in the CPV and CSP field are already known.

WO 2000007818 describes silver mirrors based on a polymeric substrate with a silver layer applied directly thereto, which in turn is covered by a polymeric protective layer which is applied directly thereto and is firmly bonded therewith. A UV-absorbing polymeric film is applied to the polymer layer.

U.S. Pat. No. 6,078,425 describes multilayer mirrors comprising reflective layers of aluminium and silver, wherein an adhesion layer of nickel and/or chromium alloys or nitrides is deposited on the aluminium surface. The silver layer is protected by a layer of nickel and/or chromium alloys or nitrides and one or more layers of metal oxides.

Starting from the known systems, which are composed of a metal layer (Al or Cu), a silver reflective layer, either a transparent protective layer of aluminium oxide or a silicon nitride layer with SiO₂ applied thereto and tantalum oxide layers, in Society of Vacuum Coaters (2009), 52nd, 473-477, the complex protective layer system is to be replaced in order to carry out mass production by means of short-cycle metallisation plants. The layer structures that are produced are still to have adequate reflectivity and weathering properties.

Society of Vacuum Coaters (2009), 52nd, 473-477 therefore discloses special multilayer structures having increased reflectivity and weathering stability. Layer structures are described which comprise a plastics substrate, a metal layer, a silver reflector applied thereto and a plasma siloxane topcoat. However, the described structure does not satisfy the required demands.

The necessity of providing highly reflective silver mirrors with a long service life for CPV applications is known from Concentrating Photovoltaic Conference 7 (CPV 7), Las Vegas, April 2011. Within this context, various possible solutions are presented in general form. There was thereby presented, inter alia, a system having the following general structure: substrate, metal, silver reflector, metal oxide, HMDSO.

In SVC/Society of Vacuum Coaters 2009, Optics 021, plasma coating is described as a simple method for producing metallic reflective and corrosion-resistant multilayer systems, and tests were carried out. It is described that, according to this method, aluminium oxide protective layers have hitherto not been used in the above-described short-cycle coatings.

For the use of reflectors in the CPV and CSP field, however, the property profile of the above-mentioned systems is inadequate in particular as regards the preservation of high reflectivity during the working life when used outside. In particular, the negative influence on the reflectivity of increased weather-related corrosion has not yet been solved satisfactorily for commercial use. Furthermore, it is to be possible to produce such multilayer systems simply and inexpensively in large numbers.

It is a common feature of the forms mentioned above that such silver mirrors are generally covered at the front with a glass plate in order to protect the underlying structure of the reflector from external influences such as weathering or mechanical stress by abrasion. According to the thickness and type of the glass plate used, the reflectivity of the reflector is reduced, as a result of which such structures lose effectiveness and thus also economy. Furthermore, the omission of a glass plate offers greater freedom in terms of the design of the resulting component as a whole.

The assembly of the reflector and the glass plate is additionally sealed at the edge in order to prevent the penetration of moisture and accordingly corrosion of the reflective layer. The reflectivity of the structure is further reduced by water that adheres in the gap between the reflector and the glass plate. Additional working steps are necessary to seal the structure, which additionally increase the costs of the structure.

The object of the present invention is, therefore, to provide a multilayer system which has constantly high reflectivity over the life cycle, the resulting reflector no longer having to be protected from external influences by a glass plate. The reflective layer is hereby located on a carrier and faces the sun directly. Incident radiation is thus reflected directly without passing through the carrier material. Such reflector arrangements are referred to as first surface mirrors.

The multilayer system further has high dimensional stability, low crack formation and a low surface roughness and as a result satisfies the requirements of DIN EN 62108 in respect of stability to climate change (Chapter 10.6, 10.7 and 10.8).

The object has been achieved by a multilayer structure according to the invention which comprises a substrate layer A, a barrier layer B, a metallic reflector layer C, an optional layer D, a plasma polymer layer E and a covering layer comprising inorganic constituents, and the covering layer does not contain UV absorber.

The present invention therefore provides a multilayer structure comprising the following layers:

Layer A: a substrate layer selected from a thermoplastic plastic, metal or glass.

Layer B: a barrier layer selected from titanium or the group of the noble metals, preferred noble metals being gold, palladium, platinum, vanadium, tantalum.

Layer C: metallic reflector layer, preferably of silver or silver alloys, the silver alloy containing amounts of less than 10 wt. % gold, platinum, palladium and/or titanium, as well as aluminium.

Layer D: optionally an oxidic layer selected from aluminium oxide (AlOx), titanium dioxide, SiO₂, Ta₂O₅, ZrO₂, Nb₂O₅ and HfO.

Layer E:

a) plasma polymer layer (anticorrosive layer) deposited from siloxane precursors; there may be mentioned, for example and preferably, hexamethyldisiloxane (HMDSO), octamethylcyclotetrasiloxane (OMCTS), octamethyltrisiloxane (OMTS), tetraethylorthosilane (TEOS) and tetramethyldisiloxane (TMDSO), decamethylcyclopentasiloxane (DMDMS), hexamethylcyclotrisiloxane (HMCTS), trimethoxymethylsilane (TMOMS), tetramethylcyclotetrasiloxane (TMCTS); HMDSO is particularly preferred,

or

in the case where layer D is of aluminium oxide or SiO₂, layer E is

b) a highly refractive metal oxide layer, the metal oxides being selected from titanium dioxide, SiO₂, Ta₂O₅, ZrO₂, Nb₂O₅ and HfO, or can be SiO₂, and a further layer according to layer E (a), that is to say a plasma polymer layer, can optionally be applied.

Layer F:

A covering layer comprising inorganic constituents (also referred to as the inorganic covering layer below), this layer not containing UV absorber.

### Layer A:

Layer A is selected from a thermoplastic plastic, metal or glass.

Thermoplastic plastics for the substrate layer are preferably polycarbonate, polystyrene, styrene copolymers, aromatic polyesters such as polyethylene terephthalate (PET), PET-cyclohexanedimethanol copolymer (PETG), polyethylene naphthalate (PEN), polybutylene terephthalate (PBT), cyclic polyolefin, poly- or copoly-acrylates and poly- or copoly-methacrylate such as, for example, poly- or copoly-methyl methacrylates (such as PMMA) as well as copolymers with styrene such as, for example, transparent polystyrene acrylonitrile (PSAN), thermoplastic polyurethanes, polymers based on cyclic olefins (e.g. TOPAS®, a commercial product of Ticona), polycarbonate blends with olefinic copolymers or graft polymers, such as, for example, styrene/acrylonitrile copolymers. Polycarbonate, PET or PETG is particularly preferred. In particular, the substrate layer is of polycarbonate.

Polycarbonates within the meaning of the present invention are both homopolycarbonates, copolycarbonates and also polyester carbonates as are described, for example, in EP-A 1,657,281.

The preparation of aromatic polycarbonates is carried out, for example, by reaction of diphenols with carbonic acid halides, preferably phosgene, and/or with aromatic dicarboxylic acid dihalides, preferably benzenedicarboxylic acid dihalides, according to the interfacial process, optionally using chain terminators, for example monophenols, and optionally using branching agents having a functionality of three or more than three, for example triphenols or tetraphenols. Preparation by a melt polymerisation process by reaction of diphenols with, for example, diphenyl carbonate is also possible.

Diphenols for the preparation of the aromatic polycarbonates and/or aromatic polyester carbonates are preferably those of formula (I)

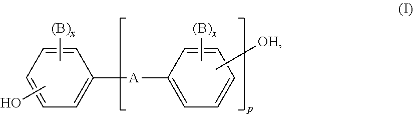

wherein
A is a single bond, C₁- to C₅-alkylene, C₂- to C₅-alkylidene, C₅- to C₆-cycloalkylidene, —O—, —SO—, —CO—, —S—, —SO₂—, C₆- to C₁₂-arylene, to which further aromatic rings optionally containing heteroatoms can be fused,
or a radical of formula (II) or (III)

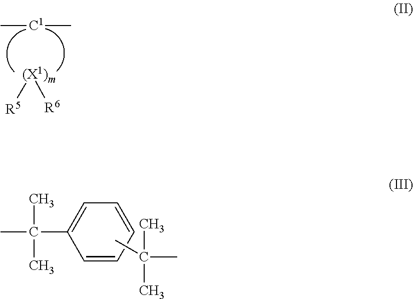

B is in each case C₁- to C₁₂-alkyl, preferably methyl, halogen, preferably chlorine and/or bromine,
x each independently of the other is 0, 1 or 2,

### P is 1 or 0, and

R⁵ and R⁶ can be chosen individually for each X¹ and each independently of the other is hydrogen or C₁- to C₆-alkyl, preferably hydrogen, methyl or ethyl,
X¹ is carbon and
m is an integer from 4 to 7, preferably 4 or 5, with the proviso that on at least one atom X¹, R⁵ and R⁶ are simultaneously alkyl.

Diphenols suitable for the preparation of the polycarbonates are, for example, hydroquinone, resorcinol, dihydroxydiphenyls, bis-(hydroxyphenyl)-alkanes, bis(hydroxyphenyl)-cycloalkanes, bis-(hydroxyphenyl)sulfides, bis-(hydroxyphenyl)ethers, bis-(hydroxyphenyl)ketones, bis-(hydroxyphenyl)-sulfones, bis-(hydroxyphenyl)-sulfoxides, alpha-alpha′-bis-(hydroxyphenyl)-diisopropylbenzenes, phthalimidines derived from isatin or phenolphthalein derivatives, as well as compounds thereof alkylated and halogenated on the ring.

Preferred diphenols are 4,4′-dihydroxydiphenyl, 2,2-bis-(4-hydroxyphenyl)-propane, 2,4-bis-(4-hydroxyphenyl)-2-methylbutane, 1,1-bis-(4-hydroxyphenyl)-p-diisopropylbenzene, 2,2-bis-(3-methyl-4-hydroxyphenyl)-propane, 2,2-bis-(3-chloro-4-hydroxyphenyl)-propane, bis-(3,5-dimethyl-4-hydroxyphenyl)-methane, 2,2-bis-(3,5-dimethyl-4-hydroxyphenyl)-propane, bis-(3,5-dimethyl-4-hydroxyphenyl)-sulfone, 2,4-bis-(3,5-dimethyl-4-hydroxyphenyl)-2-methylbutane, 1,1-bis-(3,5-dimethyl-4-hydroxyphenyl)-p-diisopropylbenzene, 2,2-bis-(3,5-dichloro-4-hydroxyphenyl)-propane, 2,2-bis-(3,5-dibromo-4-hydroxyphenyl)-propane, 1,1-bis-(4-hydroxyphenyl)-3,3,5-trimethylcyclohexane, and 2-hydrocarbyl-3,3-bis(4-hydroxyaryl)phthalimidine, as well as the reaction product of N-phenylisatin and phenol.

Particularly preferred diphenols are 2,2-bis-(4-hydroxyphenyl)-propane, 2,2-bis-(3,5-dimethyl-4-hydroxyphenyl)-propane, 2,2-bis-(3,5-dichloro-4-hydroxyphenyl)-propane, 2,2-bis-(3,5-dibromo-4-hydroxyphenyl)-propane, 1,1-bis-(4-hydroxyphenyl)-cyclohexane, and 1,1-bis-(4-hydroxyphenyl)-3,3,5-trimethylcyclohexane.

In the case of homopolycarbonates, only one diphenol is used; in the case of copolycarbonates, a plurality of diphenols is used. Suitable carbonic acid derivatives are, for example, phosgene or diphenyl carbonate.

Suitable chain terminators which can be used in the preparation of the polycarbonates are both monophenols and monocarboxylic acids. Suitable monophenols are phenol itself, alkylphenols such as cresols, p-tert-butylphenol, cumylphenol, p-n-octylphenol, p-isooctylphenol, p-n-nonylphenol and p-isononylphenol, halophenols such as p-chlorophenol, 2,4-dichlorophenol, p-bromophenol and 2,4,6-tribromophenol, 2,4,6-triiodophenol, p-iodophenol, as well as mixtures thereof. Preferred chain terminators are phenol, cumylphenol and/or p-tert-butylphenol.

Particularly preferred polycarbonates within the context of the present invention are homopolycarbonates based on bisphenol A and copolycarbonates based on monomers selected from at least one from the group comprising bisphenol A, 1,1-bis-(4-hydroxyphenyl)-3,3,5-trimethylcyclohexane, 2-hydrocarbyl-3,3-bis(4-hydroxyaryl)phthalimidines and the reaction products of N-phenylisatin and phenol. The polycarbonates can be linear or branched in known manner. The amount of comonomers, based on bisphenol A, is generally up to 60 wt. %, preferably up to 50 wt. %, particularly preferably from 3 to 30 wt. %. Mixtures of homopolycarbonate and copolycarbonates can likewise be used.

Polycarbonates and copolycarbonates comprising 2-hydrocarbyl-3,3-bis(4-hydroxyaryl)phthalimidines as monomer are known inter alia from EP 1 582 549 A1. Polycarbonates and copolycarbonates comprising bisphenol monomers based on reaction products of N-phenylisatin and phenol are described, for example, in WO 2008/037364 A1.

The thermoplastic aromatic polycarbonates have mean molecular weights (weight average M_{w}, measured by GPC (gel permeation chromatography) with polycarbonate standard) of from 10,000 to 80,000 g/mol, preferably from 14,000 to 32,000 g/mol, particularly preferably from 18,000 to 32,000 g/mol. In the case of injection-moulded polycarbonate mouldings, the preferred mean molecular weight is from 20,000 to 29,000 g/mol. In the case of extruded polycarbonate mouldings, the preferred mean molecular weight is from 25,000 to 32,000 g/mol.

The polycarbonates can further comprise fillers. Suitable fillers are glass beads, hollow glass beads, glass flakes, carbon blacks, graphite, carbon nanotubes, quartz, talc, mica, silicates, nitrides, wollastonite, as well as pyrogenic or precipitated silicas, the silicas having BET surface areas of at least 50 m²/g (according to DIN 66131/2).

Preferred fibrous fillers are metallic fibres, carbon fibres, plastics fibres, glass fibres or ground glass fibres, with particular preference being given to glass fibres or ground glass fibres. Preferred glass fibres are also those which are used in the form of rovings, long glass fibres and chopped glass fibres, which are produced from M-, E-, A-, S-, R- or C-glass, with E-, A- or C-glass being further preferred.

The diameter of the fibres is preferably from 5 to 25 μm, more preferably from 6 to 20 μm, particularly preferably from 7 to 15 μm. Long glass fibres preferably have a length of from 5 to 50 mm, more preferably from 5 to 30 mm, yet more preferably from 6 to 15 mm, and particularly preferably from 7 to 12 mm; they are described, for example, in WO-A 2006/040087. In the case of chopped glass fibres, preferably at least 70 wt. % of the glass fibres have a length of more than 60 μm.

Further inorganic fillers are inorganic particles having a particle shape selected from the group comprising spherical/cubic, tabular/discus-like and plate-like geometries. Particularly suitable are inorganic fillers with spherical or plate-like, preferably in finely divided and/or porous form with a large outer and/or inner surface area. They are preferably thermally inert inorganic materials, in particular based on nitrides such as boron nitride, oxides or mixed oxides such as cerium oxide, aluminium oxide, carbides such as tungsten carbide, silicon carbide or boron carbide, powdered quartz such as quartz flour, amorphous SiO₂, ground sand, glass particles such as glass powder, in particular glass beads, silicates or aluminosilicates, graphite, in particular highly pure synthetic graphite. Particular preference is given to quartz and talc, most preferably quartz (spherical particle shape). These fillers are characterised by a mean diameter d_{50%} of from 0.1 to 10 μm, preferably from 0.2 to 8.0 μm, more preferably from 0.5 to 5 μm.

Silicates are characterised by a mean diameter d_{50%} of from 2 to 10 μm, preferably from 2.5 to 8.0 μm, more preferably from 3 to 5 μm, and particularly preferably of 3 μm, preference being given to an upper diameter d_{95%} of from 6 to 34 μm, more preferably from 6.5 to 25.0 μm, yet more preferably from 7 to 15 μm, and particularly preferably of 10 μm. The silicates preferably have a specific BET surface area, determined by nitrogen adsorption according to ISO 9277, of from 0.4 to 8.0 m²/g, more preferably from 2 to 6 m²/g, and particularly preferably from 4.4 to 5.0 m²/g.

Further preferred silicates contain a maximum of only 3 wt. % secondary constituents, the following contents preferably applying

### Al₂O₃<2.0 wt. %,

### Fe₂O₃<0.05 wt. %,

### (CaO+MgO)<0.1 wt. %,

(Na₂O+K₂O)<0.1 wt. %, in each case based on the total weight of the silicate.

A further advantageous embodiment uses wollastonite or talc in the form of finely ground types having a mean particle diameter d₅₀ of <10 μm, preferably <5 μm, particularly preferably <2 μm, most particularly preferably <1.5 μm. The particle size distribution is determined by air classification.

The silicates can have a coating comprising organosilicon compounds, preference being given to the use of epoxysilane, methylsiloxane and methacrylsilane sizes. An epoxysilane size is particularly preferred.

The fillers can be added in an amount of up to 40 wt. %, based on the amount of polycarbonate. Preference is given to from 2.0 to 40.0 wt. %, preferably from 3.0 to 30.0 wt. %, more preferably from 5.0 to 20.0 wt. %, and particularly preferably from 7.0 to 14.0 wt. %.

Suitable blend partners for polycarbonates are graft polymers of vinyl monomers on graft bases such as diene rubbers or acrylate rubbers. Graft polymers B are preferably those of

B.1 from 5 to 95 wt. %, preferably from 30 to 90 wt. %, of at least one vinyl monomer on
B.2 from 95 to 5 wt. %, preferably from 70 to 10 wt. %, of one or more graft bases having glass transition temperatures <10° C., preferably <0° C., particularly preferably <−20° C.

The graft base B.2 generally has a mean particle size (d₅₀ value) of from 0.05 to 10 μm, preferably from 0.1 to 5 μm, particularly preferably from 0.2 to 1 μm.

Monomers B.1 are preferably mixtures of

B.1.1 from 50 to 99 parts by weight of vinyl aromatic compounds and/or vinyl aromatic compounds substituted on the ring (such as styrene, α-methylstyrene, p-methylstyrene, p-chlorostyrene) and/or methacrylic acid (C₁-C₈)-alkyl esters, such as methyl methacrylate, ethyl methacrylate, and
B.1.2 from 1 to 50 parts by weight of vinyl cyanides (unsaturated nitriles such as acrylonitrile and methacrylonitrile) and/or (meth)acrylic acid (C₁-C₈)-alkyl esters, such as methyl methacrylate, n-butyl acrylate, tert-butyl acrylate, and/or derivatives (such as anhydrides and imides) of unsaturated carboxylic acids, for example maleic anhydride and N-phenyl-maleimide.

Preferred monomers B.1.1 are selected from at least one of the monomers styrene, α-methylstyrene and methyl methacrylate, and preferred monomers B.1.2 are selected from at least one of the monomers acrylonitrile, maleic anhydride and methyl methacrylate. Particularly preferred monomers are B.1.1 styrene and B.1.2 acrylonitrile.

Graft bases B.2 suitable for the graft polymers B are, for example, diene rubbers, EP(D)M rubbers, that is to say those based on ethylene/propylene and optionally diene, acrylate, polyurethane, silicone, chloroprene and ethylene/vinyl acetate rubbers.

Preferred graft bases B.2 are diene rubbers, for example based on butadiene and isoprene, or mixtures of diene rubbers or copolymers of diene rubbers or mixtures thereof with further copolymerisable monomers (e.g. according to B.1.1 and B.1.2), with the proviso that the glass transition temperature of component B.2 is below <10° C., preferably <0° C., particularly preferably <−10° C. Pure polybutadiene rubber is particularly preferred.

Particularly preferred polymers B are, for example, ABS polymers (emulsion, mass and suspension ABS), as are described, for example, in DE-OS 2 035 390 (=U.S. Pat. No. 3,644,574) or in DE-OS 2 248 242 (=GB-PS 1 409 275) or in Ullmanns, Enzyklopadie der Technischen Chemie, Vol. 19 (1980), p. 280 ff. The gel content of the graft base B.2 is at least 30 wt. %, preferably at least 40 wt. % (measured in toluene).

The graft copolymers B are prepared by radical polymerisation, for example by emulsion, suspension, solution or mass polymerisation, preferably by emulsion or mass polymerisation.

Because, as is known, the graft monomers are not necessarily grafted onto the graft base completely during the graft reaction, graft polymers B are also understood according to the invention as being products that are obtained by (co)polymerisation of the graft monomers in the presence of the graft base and that are also formed during working up.

The polymer compositions can optionally also comprise further conventional polymer additives, such as, for example, the antioxidants, heat stabilisers, demoulding agents, optical brighteners, UV absorbers and light scattering agents described in EP-A 0 839 623, WO-A 96/15102, EP-A 0 500 496 or “Plastics Additives Handbook”, Hans Zweifel, 5th Edition 2000, Hanser Verlag, Munich, in the amounts conventional for the thermoplastics in question.

Suitable UV stabilisers are benzotriazoles, triazines, benzophenones and/or arylated cyanoacrylates.

Particularly suitable UV absorbers are hydroxy-benzotriazoles, such as 2-(3′,5′-bis-(1,1-dimethylbenzyl)-2′-hydroxy-phenyl)-benzotriazole (Tinuvin® 234, Ciba Spezialitätenchemie, Basel), 2-(2′-hydroxy-5′-(tert-octyl)-phenyl)-benzotriazole (Tinuvin® 329, Ciba Spezialitätenchemie, Basel), 2-(2′-hydroxy-3′-(2-butyl)-5′-(tert-butyl)-phenyl)-benzotriazole (Tinuvin® 350, Ciba Spezialitätenchemie, Basel), bis-(3-(2H-benztriazolyl)-2-hydroxy-5-tert-octyl)methane, (Tinuvin® 360, Ciba

Spezialitätenchemie, Basel), (2-(4,6-diphenyl-1,3,5-triazin-2-yl)-5-(hexyloxy)-phenol (Tinuvin® 1577, Ciba Spezialitätenchemie, Basel), as well as the benzophenones 2,4-dihydroxy-benzophenone (Chimasorb® 22, Ciba Spezialitätenchemie, Basel) and 2-hydroxy-4-(octyloxy)-benzophenone (Chimasorb® 81, Ciba, Basel), 2-propenoic acid, 2-cyano-3,3-diphenyl-2,2-bis[[(2-cyano-1-oxo-3,3-diphenyl-2-propenyl)oxy]-methyl]-1,3-propanediyl ester (9CI) (Uvinul® 3030, BASF AG Ludwigshafen), 2-[2-hydroxy-4-(2-ethylhexyl)oxy]phenyl-4,6-di(4-phenyl)phenyl-1,3,5-triazine (CGX UVA 006, Ciba Spezialitätenchemie, Basel) or tetra-ethyl-2,2′-(1,4-phenylene-dimethylidene)-bismalonate (Hostavin® B-Cap, Clariant AG).

The polymer composition can comprise UV absorber conventionally in an amount of from 0 to 5 wt. %, preferably from 0.1 to 2.5 wt. %, based on the total composition.

The preparation of the polymer compositions is carried out by conventional incorporation methods by combining, mixing and homogenising the individual constituents, the homogenisation in particular preferably taking place in the melt under the action of shear forces. Combining and mixing is optionally carried out before the melt homogenisation using powder premixtures.

The substrate material can be in film or sheet form. The film can be shaped and back-injected with a further thermoplastic from the above-mentioned thermoplastics (film insert moulding (FIM)). Sheets can be thermoformed or worked by means of drape forming or bent while cold. Shaping by injection moulding processes is also possible. These processes are known to the person skilled in the art.

The thickness of the substrate layer must be such that sufficient rigidity of the component is ensured.

In the case of a film, the substrate layer A can be reinforced by back injection moulding in order to ensure sufficient rigidity.

The total thickness of the layer A, that is to say including a possible back injection moulding, is generally from 1 μm to 10 mm. Particularly preferably, the thickness of layer A) is from 1 mm to 10 mm, from 1 mm to 5 mm, from 2 mm to 4 mm. In particular, the stated thicknesses relate to the total substrate thickness when using polycarbonate as substrate material, including a possible back injection moulding.

In the case of PET, the layer thickness is preferably from 10 μm to 100 μm (PET), the thickness of a PC film is preferably from 100 μm to 1 mm (PC film), it being possible for these thermoplastics to be reinforced by back injection moulding.

In the case of metallic substrates, the layer thickness is generally from 300 μm to 750 μm. In the case of glass substrates, the layer thickness is generally from 750 μm to 3 mm, preferably from 800 μm to 2 mm.

### Layer B:

Layer B is selected from the metals mentioned above. Layer B is preferably free of copper or compounds containing copper or alloys containing copper.

The thickness of layer B is generally from 40 nm to 250 nm, preferably from 55 nm to 200 nm and in particular from 80 nm to 130 nm.

The particularly preferred layer thickness when using titanium is in the range from 105 nm to 120 nm.

### Layer C:

The thickness of layer C is generally from 80 nm to 250 nm, preferably from 90 nm to 160 nm and particularly preferably from 100 nm to 130 nm.

In the case of silver, highly pure silver is used. Commercially available products are obtainable from Heraeus Precious Metals (e.g.: Target AG purity 3N7) or Umicore.

### Layer D:

The thickness of layer D is generally from 80 nm to 250 nm, preferably from 90 nm to 160 nm, particularly preferably from 90 nm to 130 nm, and most particularly preferably from 90 nm to 110 nm.

### Layer E:

The thickness of layer E is generally from 1 nm to 200 nm, preferably from 10 nm to 150 nm, particularly preferably from 20 nm to 100 nm, and most particularly preferably from 30 nm to 50 nm.

### Application of the Layers:

Layers B and C are each applied by vapour deposition or by sputtering.

Layer D is applied by reactive vapour deposition or reactive sputtering with oxygen as the reactive gas. These processes are generally known and are described, for example, in Vakuumbeschichtung, Volume 1-5, ed. Hartmut Frey, VDI Verlag, 1995.

The application of metals to the polymer can be carried out by various methods such as, for example, by vapour deposition or sputtering. The processes are described in greater detail, for example, in “Vakuumbeschichtung” Vol. 1 to 5, H. Frey, VDI-Verlag, Düsseldorf 1995 or “Oberflächen- and Dünnschicht-Technologie” Part 1, R. A. Haefer, Springer Verlag, 1987.

In order to achieve better metal adhesion and in order to clean the substrate surface, the substrates are normally subjected to a plasma pretreatment. A plasma pretreatment may alter the surface properties of polymers. These methods are described, for example, in Friedrich et al. in Metallized plastics 5 & 6: Fundamental and applied aspects and H. Grünwald et al. in Surface and Coatings Technology 111 (1999) 287-296.

Layer E is applied in a PECVD (plasma enhanced chemical vapour deposition) or plasma polymerisation process. In such processes, low-boiling precursors based mainly on siloxane are vaporised into a plasma and thereby activated, so that they are able to form a film. The process is described inter alia in Surface and Coatings Technology 111 (1999), 287-296.

### Layer F:

Inorganic covering layers within the meaning of the present invention are lacquers which are prepared by the sol-gel process. The sol-gel process is a process for the synthesis of non-metallic inorganic or hybrid polymeric materials from colloidal dispersions, the so-called sols. Inorganic covering layers which have been prepared by the sol-gel process are available commercially under the name Silfort PHC587, Silfort PHC587B, Silfort PHC587C, Silfort SHC5020, Silfort AS4000 and Silfort AS4700 (Momentive Performance Materials), CrystalCoat 6000 (SDC Technologies), PERMA-NEW 6000 (or PERMA-NEW 6000B) CLEAR HARD COATING SOLUTION (California Hardcoating Co.) as well as KASI flex and KASI sunflex (KRD).

The covering layer is characterised in that it does not contain UV absorber.

For example, sol-gel coating solutions can be prepared by hydrolysis of aqueous dispersions of colloidal silicon dioxide and an organoalkoxysilane and/or an alkoxysilane or mixtures of organoalkoxysilanes of the general formula RSi(OR′)₃ and/or alkoxysilanes of the general formula Si(OR′)4, wherein in the organoalkoxysilane(s) of the general formula RSi(OR′)3 R represents a monovalent C1- to C6-alkyl radical or a wholly or partially fluorinated C1-C6-alkyl radical, a vinyl unit or an allyl unit, an aryl radical or a C1-C6-alkoxy group. R is particularly preferably a C1- to C4-alkyl group, a methyl, ethyl, n-propyl, isopropyl, tert-butyl, sec-butyl or n-butyl group, a vinyl, allyl, phenyl or substituted phenyl unit. The —OR′ are selected independently of one another from the group containing C1- to C6-alkoxy groups, a hydroxy group, a formyl unit and an acetyl unit. Sol-gel polysiloxane lacquers in some cases also fall under the definition of a hybrid lacquer.

Colloidal silicon dioxide is obtainable, for example, as Levasil 200 A (HC Starck), Nalco 1034A (Nalco Chemical Co), Ludox AS-40 or Ludox LS (GRACE Davison). The following compounds may be mentioned as examples of organoalkoxysilanes: 3,3,3-trifluoropropyltrimethoxysilane, methyltrimethoxysilane, methyltrihydroxysilane, methyltriethoxysilane, ethyltrimethoxysilane, methyltriacetoxysilane, ethyltriethoxysilane, phenyltrialkoxysilane (e.g. phenyltriethoxysilane and phenyltrimethoxysilane) and mixtures thereof. The following compounds may be mentioned as examples of alkoxysilanes: tetramethoxysilane and tetraethoxysilane and mixtures thereof.

Organic and/or inorganic acids and bases, for example, can be used as catalysts.

In one embodiment, the colloidal silicon dioxide particles can also be formed in situ starting from alkoxysilanes by preliminary condensation (see in this connection “The Chemistry of Silica”, Ralph K. Iler, John Wiley & Sons, (1979), p. 312-461).

The hydrolysis of the sol-gel solution is terminated or slowed considerably by addition of solvents, preferably alcoholic solvents such as, for example, isopropanol, n-butanol, isobutanol or mixtures thereof. This is followed by an ageing step of a few hours or several days/weeks. Additives and/or stabilisers such as, for example, flow improvers, surface additives, thickeners, pigments, colourants, curing catalysts, IR absorbers, UV absorbers and/or adhesion promoters can further be added. The use of hexamethyldisilazane or comparable compounds, which can lead to a reduced susceptibility of the coatings to cracking, is also possible (see also WO 2008/109072 A).

Hybrid lacquers within the meaning of the present invention are based on the use of hybrid polymers as binders. Hybrid polymers (hybrid: lat. “of dual origin”) are polymer-based materials that combine structural units of different material classes at the molecular level. As a result of their structure, hybrid polymers can exhibit wholly novel property combinations. Unlike composite materials (defined phase boundaries, weak interactions between the phases) and nanocomposites (use of nanoscale fillers), the structural units of hybrid polymers are linked together at the molecular level. That is achieved by chemical processes such as, for example, the sol-gel process, with which inorganic networks can be built up. By using organically reactive precursors, for example organically modified metal alkoxides, organic oligomer/polymer structures can additionally be produced. Acrylate lacquers which comprise surface-modified nanoparticles and form an organic/inorganic network after curing are likewise defined as hybrid lacquers. There are thermally curable and UV-curable hybrid lacquers.

There are preferably used as layer F thermally curable sol-gel lacquers without additional UV absorbers, as are obtainable, for example, from Momentive Performance Materials under the product name SHC5020. Sol-gel polysiloxane lacquers are used in layer thicknesses of from 1 to 20 μm, preferably from 2 to 15 μm, particularly preferably from 4 to 12 μm.

If layer D in the layer structure according to the invention comprises aluminium oxide, the covering layer F is preferably formed by an inorganic lacquer system.

A primer can optionally be used between the inorganic covering layer F and layer E. The function of the primer is to ensure adhesion between these two layer systems. Preferred primers are based on poly(meth)acrylates, preferably polymethyl methacrylate (PMMA), and are available commercially from Momentive Performance Materials under the product name SHP401, SHP470 or SHP470FT. These are conventionally used in layer thicknesses of from 50 nm to 4 μm, preferably from 100 nm to 1.3 μm (SHP401) and from 1.2 μm to 4 μm (SHP470 and SHP470FT).

The application of the inorganic covering layers as well as primer is preferably carried out by flood coating, pouring, knife coating, spraying, roller coating or dipping, in particular by flood coating, pouring or spraying.

The curing temperatures of the inorganic covering layer are preferably less than or equal to 100° C. if layer D is used in the overall structure of the present invention.

In an alternative embodiment of the present invention, layer D is free of aluminium oxide and curing of layer F takes place at temperatures greater than 100° C.

In a further preferred embodiment, the inorganic covering layers of layer F are applied by chemical gas phase deposition, a PECVD (plasma enhanced chemical vapour deposition) or plasma polymerisation process. In such processes, low-boiling precursors based mainly on siloxane are vaporised into a plasma and thereby activated, so that they are able to form a film.

There are used as precursors, for example and preferably, hexamethyldisiloxane (HMDSO), octamethylcyclotetrasiloxane (OMCTS), octamethyltrisiloxane (OMTS), tetraethylorthosilane (TEOS) and tetramethyldisiloxane (TMDSO), decamethylcyclopentasiloxane (DMDMS), hexamethylcyclotrisiloxane (HMCTS), trimethoxymethylsilane (TMOMS), tetramethylcyclotetrasiloxane (TMCTS); HMDSO is particularly preferably used.

Preferred layer thicknesses are greater than or equal to 1 μm. The mechanical stability of the resulting layers can be varied by means of the oxygen-to-precursor ratio. The preferred ratio depends on the precursor used. For HMDSO, the preferred ratio of oxygen to HMDSO is from 50 to 1, particularly preferably from 30 to 1 and most particularly preferably from 20 to 5.

The process is described inter alia in Surface and Coatings Technology 111 (1999), 287-296.

### EXAMPLES

### Production of the Sheet

Rectangular injection-moulded sheets of dimensions 150×105 x 3.2 mm, with side gate, were produced. The melt temperature was 300-330° C. and the tool temperature was 100° C. The granules in question were dried for 5 hours in a vacuum drying cabinet at 120° C. prior to processing.

PC-1: Makrolon® 2407, Bayer MaterialScience AG, Leverkusen, Germany, with a melt volume-flow rate (MVR) of 19 cm³/10 min, measured according to ISO 1133 at 300 and 1.2 kg.

PC-2: Makrolon® GP U099, Bayer MaterialScience AG, Leverkusen, Germany, with a melt volume-flow rate (MVR) of 10 cm^{3/10} min, measured according to ISO 1133 at 300 and 1.2 kg.

### Example 1

### Multilayer Structure—According to the Invention

The PC sheet (PC-1) was coated according to the following description. The following layer structure was produced:

3.2mm substrate\\110 nm Ti\\120 nm Ag\\100 nm AlOx\\40 nm HMDSO

### Production Process:

1. The PC sheet was introduced into the vacuum chamber, which was evacuated to p<2·10⁻⁵ mbar.
2. Plasma pretreatment: The PC sheet was pretreated for 1 minute at 500 W and 0.1 mbar Ar in mid-frequency plasma (40 kHz).
3. Layer B: The titanium layer was deposited by means of DC sputtering. There was used as the coating source an ION′X-8″HV round planar magnetron from Thin Film Consulting having a diameter of 200 mm, which was operated by a “Pinnacle™ Plus+ 5 kW” generator from Advanced Energy. The target (here: titanium) was first sputter-cleaned for 1 minute with the shutter closed, and then the titanium layer was deposited on the PC sheet in the course of 3 min 40 s at 2000 W and a pressure of p=5·10⁻³ mbar with the shutter open.
4. Layer C: The silver layer was deposited by means of DC sputtering. There was used as the coating source an ION′X-8″HV round planar magnetron from Thin Film Consulting having a diameter of 200 mm, which was operated by a “Pinnacle™ Plus+ 5 kW” generator from Advanced Energy. The target (here: silver) was first sputter-cleaned for 1 minute with the shutter closed, and then the silver layer was deposited on the titanium layer in the course of 51 at 2000 W and a pressure of p=5·10⁻³ mbar with the shutter open.

The coated PC sheet was then removed from the coating installation, and the coating installation was prepared for the final layers.
5. The coated PC sheet was again introduced into the vacuum chamber, which was evacuated to p<2·10⁻⁵ mbar.
6. Plasma pretreatment: The coated PC sheet was pretreated for 1 min at 500 W and 0.1 mbar Ar in mid-frequency plasma (40 kHz).
7. Layer D: The AlOₓ layer was deposited by means of reactive pulsed DC sputtering with a pulse frequency of 150 kHz. There was used as the coating source an ION′X-8″HV round planar magnetron from Thin Film Consulting having a diameter of 200 mm, which was operated by a “Pinnacle™ Plus+ 5 kW” generator from Advanced Energy. The target (here: aluminium) was first sputter-cleaned for 1 minute with the shutter closed, and then the AlOₓ layer was deposited on the silver layer in the course of 4 min at 340 V in voltage-regulated mode and at a total pressure of p=5·10⁻³ mbar with the shutter open. The O₂/Ar ratio was adjusted to 8%.
8. Layer E: HMDSO (hexamethyldisiloxane) was applied to the AlOₓ layer as a further protective layer by means of plasma polymerisation. The layer was applied for 35 s at a starting pressure of p=0.038 mbar and flow of 90 sscm HMDSO and 1500 W mid-frequency power (40 kHz). There was used as the source a parallel reactor unit with a plate gap of about 200 mm, the plate being located in the middle. The source was operated by an Advanced Energy PEII (5 kW) incl. LMII high-voltage transformer.

The sheet was rotated above the coating sources at about 20 rpm during all the coating steps, in order to increase the homogeneity of the coating.

### Example 2

### Multilayer Structure—According to the Invention

The PC sheet (PC-1) was coated according to the following description. The following layer structure was produced:

3.2mm substrate\\110 nm Ti\\120 nm Ag\\40 nm HMDSO

### Production Process:

1. The PC sheet was introduced into the vacuum chamber, which was evacuated to p<2·10⁻⁵ mbar.
2. Plasma pretreatment: The PC sheet was pretreated for 1 minute at 500 W and 0.1 mbar Ar in mid-frequency plasma (40 kHz).
3. Layer B: The titanium layer was deposited by means of DC sputtering. There was used as the coating source an ION′X-8″HV round planar magnetron from Thin Film Consulting having a diameter of 200 mm, which was operated by a “Pinnacle™ Plus+ 5 kW” generator from Advanced Energy. The target (here: titanium) was first sputter-cleaned for 1 minute with the shutter closed, and then the titanium layer was deposited on the PC sheet in the course of 3 min 40 s at 2000 W and a pressure of p=5·10⁻³ mbar with the shutter open.
4. Layer C: The silver layer was deposited by means of DC sputtering. There was used as the coating source an ION′X-8″HV round planar magnetron from Thin Film Consulting having a diameter of 200 mm, which was operated by a “Pinnacle™ Plus+ 5 kW” generator from Advanced Energy. The target (here: silver) was first sputter-cleaned for 1 minute with the shutter closed, and then the silver layer was deposited on the titanium layer in the course of 51 at 2000 W and a pressure of p=5·10⁻³ mbar with the shutter open.

The coated PC sheet was then removed from the coating installation, and the coating installation was prepared for the final layers.
5. The coated PC sheet was again introduced into the vacuum chamber, which was evacuated to p<2·10⁻⁵ mbar.
6. Plasma pretreatment: The coated PC sheet was pretreated for 1 min at 500 W and 0.1 mbar Ar in mid-frequency plasma (40 kHz).
7. Layer E: HMDSO (hexamethyldisiloxane) was applied to the silver layer as a further layer by means of plasma polymerisation. The layer was applied for 35 s at a starting pressure of p=0.038 mbar and flow of 90 sscm HMDSO and 1500 W mid-frequency power (40 kHz). There was used as the source a parallel reactor unit with a plate gap of about 200 mm, the plate being located in the middle. The source was operated by an Advanced Energy PEII (5 kW) incl. LMII high-voltage transformer.
8. Plasma pretreatment: The coated PC sheet was pretreated for 1 min at 500 W and 0.1 mbar O₂ in mid-frequency plasma (40 kHz).

The sheet was rotated above the coating sources at about 20 rpm during all the coating steps, in order to increase the homogeneity of the coating.

### Adjustment of the Layer Thicknesses:

For the adjustment of the layer thicknesses, a calibration of the process parameters was first carried out. To that end, different layer thicknesses were deposited with defined process parameters on a specimen holder which was provided with an adhesive strip in the middle in order to produce a step. After deposition of the layer in question, the adhesive strip was removed and the height of the step that had been formed was determined using a KLA Tencor Alpha-Step 500 surface profiler from Tencor Instruments.

Process parameters that must be set in order to produce the desired target layer thickness are thereby determined.

### Measurement of the Layer Thickness on the Finished Part:

The layer thickness can be determined on the finished part by means of TOF-SIMS (time of flight-secondary ion mass spectrometry) or by XPS (X-ray photospectroscopy) in combination with TEM (transmission electron microscopy).

### Applications of the Covering Layers (Layers F):

In the following examples, the following commercially available covering layer systems from Momentive Performance Materials were used.
SHP401: PMMA solution in organic solvents
AS4000: thermally curable inorganic covering lacquer containing UV absorber
SHC5020: thermally curable inorganic covering lacquer without UV absorber
UVHC300: radiation-curable organic covering lacquer containing UV absorber
UVHC7800: radiation-curable organic covering lacquer without UV absorber

### Example 3a

### Application of SHP401/SHC5020 to the Layer Sequence of Example 2 at a High Baking Temperature (According to the Invention)

Application of primer SHP401 to layer E of the layer sequence of Example 1 was carried out at 21° C. and 34% relative humidity by flood coating. During a subsequent flash-off time of 30 minutes in the above-mentioned climate, residual solvents present in the lacquer layer were able to evaporate off. Application of the coating composition SHC5020 to the primer layer was then carried out, likewise at 21° C. and 34% relative humidity by flood coating. During a subsequent flash-off time of 30 minutes in the above-mentioned climate, residual solvents present in the lacquer layer were able to evaporate off. Finally, the layer system consisting of SHP401 and SHC5020 was cured at 130° C. for 30 minutes in a circulating-air drying cabinet.

### Example 3b

### Application of SHC5020 to the Layer Sequence of Example 2 at a High Baking Temperature (According to the Invention)

Application of the coating composition SHC5020 to layer E of the layer sequence of Example 2 was carried out at 21° C. and 34% relative humidity by flood coating. During a subsequent flash-off time of 30 minutes in the above-mentioned climate, residual solvents present in the lacquer layer were able to evaporate off.

Finally, the layer system consisting of SHC5020 was cured at 130° C. for 30 minutes in a circulating-air drying cabinet.

A visual examination of the layer sequences of Examples 3a and 3b was carried out after their production.

| Example | Result of the visual examination |
|---|---|
| 3a | no defects; the surface is intact |
| 3b | no defects; the surface is intact |

### Weathering Results:

### Test and Evaluation Methods:

| Test | Conditions | Time (h) | Assessment |
|---|---|---|---|
| Climate change test | 100 cycles from −40° C. to 110° C. | about 650 h | Determination |
| (DIN EN 62108 | (14 cycles per day) followed by 20 cycles | | of RI |
| 10.6 & 10.8) | humidity/frost test (20 h at 85° C./85% | | |
| | relative humidity followed by 4 h cooling | | |
| | to −40° C. and then reheating to | | |
| | 85° C./85% relative humidity) | | |
| Xenon test | 0.75 W/m²/nm at 340 nm, boro-boro | 500 h | Determination |
| | filter, black panel temperature 70° C., | | of RI |
| | 50% relative humidity, without rain | | |
| Damp Heat Test | 85° C., 85% relative humidity | 2000 h | Determination |
| (DIN EN 62108 | | | of RI |
| 10.7) | | | |
| Dry Heat Test | In circulating-air drying cabinet at 125° C. | 1000 h | Determination |
| | | | of RI |

### Determination of RI (Reflection Index):

1. Determination of total (Rₜₒₜₐₗ) and diffuse (R_{diffuse}) reflectance by means of a Perkin Elmer Lambda 900 photospectrometer, calibrated to Spektralon standard in the range λ=200-1100 nm
2. Calculation of the direct reflection: R_{direct}=Rₜₒₜₐₗ−R_{diffuse}
3. Calculation of

$${RI}_{i} = \frac{1}{Norm} {Σ}_{i} {\overline{R}}_{direct} ( λ ) \cdot EQE ( λ ) \cdot SP ( λ )$$

where i=1, 2, 3
4. Where RI=min (RIᵢ) where i=1, 2.
   EQEᵢ(λ) (external quantum efficiency): e.g. Spectrolab C1MJ
   SP(λ): solar spectrum according to ASTM G173-03

### Direct Reflectance and RI—Initial Values:

| R_{direct} | RI | 400 nm | 500 nm | 700 nm | 900 nm |
|---|---|---|---|---|---|
| Ex. 3a | 96.05 | 89.29 | 96.19 | 97.99 | 98.26 |
| Ex. 3b | 95.90 | 89.53 | 95.95 | 97.73 | 97.76 |

RI after Weathering:

| | Climate change | Xenon test | Damp Heat | Dry Hot |
|---|---|---|---|---|
| | test | (after | Test | Test |
| RI | 100TC + 20 HF | 500 h) | 2000 h | 1000 h |
| Ex. 3a | 95.00 | 93.63 | 94.38 | 95.21 |
| Ex. 3b | 94.90 | 90.87 | 94.95 | 96.45 |

The results of test series 3 show that the reflectivity of the layer systems is not substantially affected after the ageing tests which were carried out. The layer structure comprising layers A to E is adequately protected by layer F.

### Example 4a

### Application of SHP401/AS4000 to the Layer Sequence of Example 1 at a High Baking Temperature (Comparison)

Application of primer SHP401 to layer E of the layer sequence of Example 1 was carried out at 21° C. and 32% relative humidity by flood coating. During a subsequent flash-off time of 30 minutes in the above-mentioned climate, residual solvents present in the lacquer layer were able to evaporate off. Application of the coating composition AS4000 to the primer layer was then carried out, likewise at 21° C. and 32% relative humidity by flood coating. During a subsequent flash-off time of 30 minutes in the above-mentioned climate, residual solvents present in the lacquer layer were able to evaporate off. Finally, the layer system consisting of SHP401 and AS4000 was cured at 130° C. for 60 minutes in a circulating-air drying cabinet.

### Example 4b

### Application of SHP401/AS4000 to the Layer Sequence of Example 1 at a Low Baking Temperature (Comparison)

Application of primer SHP401 to layer E of the layer sequence of Example 1 was carried out at 22° C. and 32% relative humidity by flood coating. During a subsequent flash-off time of 30 minutes in the above-mentioned climate, residual solvents present in the lacquer layer were able to evaporate off. Application of the coating composition AS4000 to the primer layer was then carried out, likewise at 22° C. and 32% relative humidity by flood coating. During a subsequent flash-off time of 30 minutes in the above-mentioned climate, residual solvents present in the lacquer layer were able to evaporate off. Finally, the layer system consisting of SHP401 and AS4000 was cured at 100° C. for 120 minutes in a circulating-air drying cabinet.

### Example 4c

### Application of SHC5020 to the Layer Sequence of Example 1 at a Low Baking Temperature (According to the Invention)

Application of the coating composition SHC5020 to layer E of the layer sequence of Example 1 was carried out at 22° C. and 32% relative humidity by flood coating. During a subsequent flash-off time of 30 minutes in the above-mentioned climate, residual solvents present in the lacquer layer were able to evaporate off.

Finally, the layer system consisting of SHC5020 was cured at 100° C. for 120 minutes in a circulating-air drying cabinet.

### Example 4d

### Application of UVHC3000 to the Layer Sequence of Example 1 (Comparison)

Application of the coating composition UVHC3000 to layer E of the layer sequence of Example 1 was carried out at 21° C. and 32% relative humidity by flood coating. During a subsequent flash-off time of 2 minutes in the above-mentioned climate followed by a further flash-off time of 6 minutes at 75° C. in a circulating-air drying cabinet, residual solvents present in the lacquer layer were able to evaporate off.

Finally, curing of the lacquer layer was carried out by UV radiation of a Hg radiator in a UV installation from IST (type IST M 50 2X1 URS-TR-SS) with a total dose of about 4 J/cm² determined using a UV-4C SD UV dosimeter from UV-Technik Meyer GmbH.

### Example 4e

### Application of UVHC7800 to the Layer Sequence of Example 1 (Comparison)

Application of the coating composition UVHC7800 to layer E of the layer sequence of Example 1 was carried out at 21° C. and 32% relative humidity by flood coating. During a subsequent flash-off time of 2 minutes in the above-mentioned climate followed by a further flash-off time of 6 minutes at 75° C. in a circulating-air drying cabinet, residual solvents present in the lacquer layer were able to evaporate off.

Finally, curing of the lacquer layer was carried out by UV radiation of a Hg radiator in a UV installation from IST (type IST M 50 2X1 URS-TR-SS) with a total dose of about 4 J/cm² determined using a UV-4C SD UV dosimeter from UV-Technik Meyer GmbH.

### Results (C=Comparison, I=According to the Invention)

A visual examination of the layer sequences of Examples 4a to 4e was carried out after their production.

| Example | Result of the visual examination |
|---|---|
| 4a C | formation of microcracks in the layer structure |
| 4b C | formation of small star-shaped cracks in the layer structure |
| 4c I | no defects; the surface is intact |
| 4d C | partial delamination after cutting |
| 4e C | no defects; the surface is intact, slight wetting damage |

Furthermore, the reflection index (RI) were.

| Example | RI |
|---|---|
| 4a C | 94.3 |
| 4b C | 96.1 |
| 4c I | 95.6 |
| 4d C | 96.5 |
| 4e C | 94.7 |

Samples 4a and 4e show that the overlacquering and curing of layer sequences A to E with the layer system F should take place at temperatures below or equal to 100° C. in order to obtain an overall composite that does not have any visual defects and at the same time has excellent reflection properties.

Samples 4c and 4e were further subjected to accelerated ageing of 500 hours and 1000 hours. To that end, a weathering device from Atlas (CI series) with the following parameters was used:
radiation strength: 0.75 W/m²/nm at 340 nm wavelength
filter: boro-boro filter
black panel temperature: 70° C.
relative humidity: 50%
no rain

| Example | RI | Observations |
|---|---|---|
| 4c - 500 hours | 96.00 | no defects; the surface is intact |
| 4c - 1000 hours | 93.98 | no defects; the surface is intact |
| 4e - 500 hours | 96.11 | partial delamination |

The results of test series 4 show that layer F, consisting of an inorganic covering layer system which does not contain UV absorber, has significantly improved weathering behaviour under stress according to EN ISO 62108 than a multilayer composite in which layer F consists of an organic covering lacquer without UV absorber.

Application tests on the covering layers of Examples 4a to 4e) applied to a transparent substrate were carried out, referred to as Example 5 below:

### Example 5a

### Application of SHP401/AS4000 to Transparent PC-2 at a High Baking Temperature Using the Parameters of Example 4a

### Example 5b

### Application of SHP401/AS4000 to Transparent PC-2 at a Low Baking Temperature Using the Parameters of Example 4b

### Example 5c

### Application of SHC5020 to Transparent PC-2 at a Low Baking Temperature Using the Parameters of Example 4c

### Example 5d

### Application of UVHC3000 to Transparent PC-2 Using the Parameters of Example 4d

### Example 5e

### Application of UVHC7800 to Transparent PC-2 Using the Parameters of Example 4e

### Example 5f

### Layer Structure without Covering Lacquer F of Example 1

The abrasion of the layers of Examples 5a to 5e was determined by means of Taber Industries 5151 Abraser after 1000 rotations using CS10F wheels and a load of 500 g per friction wheel. The increase in haze before and after the treatment was determined by means of Haze Guard from BYK Gardner. In the case of sample 5f, the treatment was terminated after 15 rotations.

The acetone resistance of the layers of Examples 5a to 5f was determined. To that end, a cotton wool swab was immersed in acetone, placed on the surface to be tested and covered with a watchglass in order to prevent the test medium from evaporating. The result given was the time at which the surface exhibited no alteration.

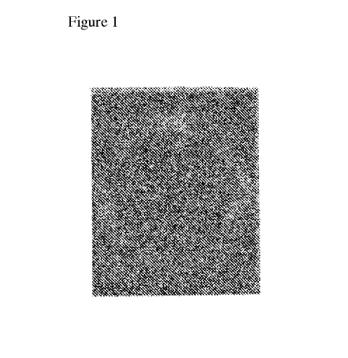

The pencil hardness of the layers of Examples 5a to 5f was determined analogously to ISO 15184 using pencils from Cretacolor under a load of 750 g. The result given was the pencil hardness with which no marking could be produced on the surface to be tested.

| | | | Pencil |
|---|---|---|---|
| | Abrasion | Acetone | hardness |
| | determination | resistance | [degree of |
| Sample number | in [%] | in [minutes] | hardness] |
| 5a C | 3.0 | 60 | F |
| 5b C | 7.8 | 5 | F |
| 5c I | 2.2 | 30 | F |
| 5d C | 3.9 | 60 | H |
| 5e C | 2.4 | 60 | H |
| 5f C | Layer is destroyed | <15 | <6B |
| | after 15 rotations - | | |
| | see FIG. 1 | | |

Example 5 shows that, without covering lacquer, the requirement of mechanical stability and high resistance to chemicals cannot be achieved. Unprotected layer systems, as in Example 5f, must be positioned behind separate glazing in the respective application.

The light-grey ring in FIG. 1 shows that the layers are destroyed after 15 rotations.

### CONCLUSION

It is clear from the present invention that, as a result of the covering layers (layers F) applied to the reflective layer systems (layers A to E), it is possible to obtain reflectors which have long-term stability and are able to withstand aggressive chemicals as well as high mechanical stress. The reflectivity of the structures having an inorganic covering lacquer without UV absorber remains at a high level even after they have been subjected to stress in accordance with DIN EN 62108.

1. A multilayer structure comprising
layer A: a substrate layer selected from a thermoplastic plastic, metal or glass,
layer B: a barrier layer selected from titanium or the group of the noble metals,
layer C: metallic reflector layer,
layer D: optionally an oxidic layer selected from aluminium oxide (AlOx), titanium dioxide, SiO₂, Ta₂O₅, ZrO₂, Nb₂O₅ and HfO,
layer E:
a) is a plasma polymer layer (anticorrosion layer) deposited from siloxane precursors
or
in the case where layer D is aluminium oxide or SiO₂, layer E is
b) a highly refractive metal oxide layer, the metal oxides being selected from titanium dioxide, SiO₂, Ta₂O₅, ZrO₂, Nb₂O₅ and HfO, or can be SiO₂, and a further layer according to layer E (a), a plasma polymer layer, can optionally be applied,
layer F:
a covering layer comprising inorganic constituents, this layer F not containing UV absorber.

2. Multilayer structure according to claim 1, wherein the thermoplastic plastic is selected from at least one of the group consisting of polycarbonate, polystyrene, styrene copolymers, aromatic polyesters, cyclic polyolefins, poly- or copoly-acrylates and poly- or copoly-methacrylate, copolymers with styrene, thermoplastic polyurethanes, polymers based on cyclic olefins, polycarbonate blends with olefinic copolymers or graft polymers.

3. Multilayer structure according to claim 1, wherein layer B is of titanium.

4. Multilayer structure according to claim 1, wherein layer C is of silver or silver alloys, wherein the silver alloy comprises amounts of less than 10 wt. % gold, platinum, palladium and/or titanium, as well as aluminium.

5. Multilayer structure according to claim 4, wherein layer C is of silver.

6. Multilayer structure according to claim 1, wherein layer D is of aluminium oxide (AlOx) or titanium dioxide.

7. Multilayer structure according to claim 1, wherein layer E is hexamethyldisiloxane.

8. Multilayer structure according to claim 1, wherein the layer thicknesses of the layers are as follows:
total thickness of layer A: from 1 μm to 10 mm in the case of thermoplastics, from 300 μm to 750 μm in the case of metallic substrates, from 750 μm to 3 mm in the case of glass,
layer B: from 40 nm to 250 nm,
layer C: from 80 nm to 250 nm,
layer D: from 80 nm to 250 nm,
layer E: from 1 nm to 200 nm,
layer F: from 1 μm to 20 μm.

9. Multilayer structure according to claim 1, wherein layer F is sol-gel lacquers which are prepared by hydrolysis of aqueous dispersions of colloidal silicon dioxide and an organoalkoxysilane and/or an alkoxysilane or mixtures of organoalkoxysilanes of the general formula RSi(OR′)3 and/or alkoxysilanes of the general formula Si(OR′)4, wherein in the organoalkoxysilane(s) of the general formula RSi(OR′)3 R represents a monovalent C1- to C6-alkyl radical or a wholly or partially fluorinated C1-C6-alkyl radical, a vinyl unit or an allyl unit, an aryl radical or a C1-C6-alkoxy group.

10. Multilayer structure according to claim 1, wherein the layer thickness of layer B is from 80 to 130 nm.

11. Multilayer structure according to claim 1, wherein the layer thickness of layer C is from 90 nm to 160 nm, the layer thickness of layer D is from 90 nm to 160 nm, and the layer thickness of layer E is from 20 nm to 100 nm.

12. Multilayer structure according to claim 1, wherein the thermoplastic is selected from the group consisting of polycarbonate, aromatic polyesters and polycarbonate blends, wherein these thermoplastics can comprise fillers.

13. A method comprising utilizing the multilayer structure according to claim 1 as a reflector in photovoltaic modules, solar modules, in lighting systems, as a mirror in the residential field as well as in the automotive field, as a reflector in fibre-optic systems.

14. Photovoltaic modules, solar modules, lighting systems, fibre-optic systems comprising a multilayer structure according to claim 1.

15. Mirror comprising a multilayer structure according to claim 1.
